(19) United States
(12) Patent Application Publication
(10) Pub. No.: US 2026/0346599 A1
(43) Pub. Date: Nov. 5, 2026

(54) PRINTING DEVICE AND PRINTING METHOD

(71) Applicant: FUJI CORPORATION, Chiryu (JP)

(72) Inventors: Kazuma ISHIKAWA, Chiryu-shi (JP); Mitsuaki KATO, Anjo-shi (JP)

(73) Assignee: FUJI CORPORATION, Chiryu (JP)

(21) Appl. No.: 19/485,895

(22) PCT Filed: Jun. 7, 2023
(86) PCT No.: PCT/JP2023/021230

§ 371 Date: Nov. 19, 2025

(51) Int. Cl. B41F 15/36; B41F 15/08; B41F 15/22; B41F 33/00; B41M 1/12

(52) U.S. Cl. CPC B41F 15/36; B41F 15/0813; B41F 15/22; B41F 33/00; B41M 1/12

(57) ABSTRACT

A printing device includes a mask work section to place and fix a screen mask so that the screen mask is insertable and removable; a target processing section to convey and fix a processing target; a mask stopper to move on the mask work section, to abut against the screen mask, and to stop the screen mask at a predetermined position; a storage section to store information; and a control section to execute a positioning process of acquiring position information indicating that the screen mask fixed to the mask work section and the processing target fixed to the target processing section are aligned with each other at a predetermined printing position, to cause the storage section to store the acquired position information, and to cause the mask stopper to be disposed, based on the stored position information, at a placement position where the screen mask stops at the aligned position.

### TECHNICAL FIELD

The present description discloses a printing device and a printing method.

### BACKGROUND ART

Conventionally, for example, in a printing device that executes a printing process of a viscous fluid onto a processing target such as a board using a screen mask, there has been proposed a printing device in which a worker inputs information such as a size and an opening position of the screen mask, and a stopper for positioning the screen mask is disposed at a position corresponding to the input information (for example, refer to Patent Literature 1). In this printing device, since the stopper is disposed on a printing head so as to be movable, even when the size of the screen mask or the like changes, the printing device can easily accommodate such changes.

### CITATION LIST

### Patent Literature

Patent Literature 1: JP-A-2006-289815

### BRIEF SUMMARY

### Technical Problem

However, in the printing device of Patent Literature 1 described above, since the printing device is configured to input a type value of the screen mask, the state of each individual screen mask is not accommodated. Accordingly, in order to execute a high-precision printing process after the screen mask has been stopped by the stopper, it is necessary to execute a higher-precision positioning process between the screen mask and the board. Further, in the printing device of Patent Literature 1, when the screen mask is moved by, for example, cleaning, addition of solder, insertion of a board, or the like, after the positioning process is executed, the positioning process has to be further executed. Since the execution of the positioning process consumes time, the printing device of Patent Literature 1 may be unable to execute the printing process efficiently.

The present disclosure has been made in view of such problems, and a main object of the present disclosure is to provide a printing device and a printing method capable of executing a printing process more efficiently.

### Solution to Problem

The printing device and the printing method disclosed in the present description adopt the following means to achieve the main object described above.

The printing device disclosed in the present description is a printing device for printing, using a squeegee, a viscous fluid that is placed on an upper surface of a screen mask, onto a processing target, the printing device including:
a mask work section configured to place and fix a screen mask so that the screen mask is insertable and removable;
a target processing section configured to convey and fix a processing target;
a mask stopper configured to move on the mask work section, to abut against the screen mask, and to stop the screen mask at a predetermined position;
a storage section configured to store information; and
a control section configured to execute a positioning process of acquiring position information indicating that the screen mask fixed to the mask work section and the processing target fixed to the target processing section are aligned with each other at a predetermined printing position, to cause the storage section to store the acquired position information, and to cause the mask stopper to be disposed, based on the stored position information, at a placement position where the screen mask stops at the aligned position.

In this printing device, once the positional information indicating that the screen mask and the processing target are aligned with each other is acquired, since the mask stopper is disposed at the placement position based on the positional information, re-execution of the positioning process can be omitted, so that the printing process can be executed more efficiently.

### BRIEF DESCRIPTION OF DRAWINGS

FIG. 1 is a schematic view illustrating an example of mounting system 10.

FIG. 2 is a diagram illustrating an example of printing section 24, mask work section 30, and board processing section 35.

FIG. 3 is a flowchart illustrating an example of a printing process routine.

FIG. 4 is a diagram illustrating an example of position confirmation using mark camera 42 in the printing process.

FIG. 5 is a diagram illustrating an example of a printing operation by squeegees 27 in the printing process.

FIG. 6 is a diagram illustrating an example of standby at a placement position of mask stopper 28.

FIG. 7 is a diagram illustrating an example of a position adjustment process when screen mask M is excessively pushed in.

FIG. 8 is a diagram illustrating an example of a position adjustment process when screen mask M has not reached mask stopper 28.

### DESCRIPTION OF EMBODIMENTS

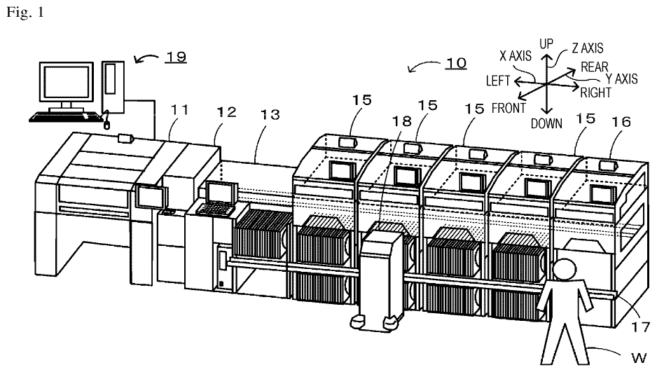

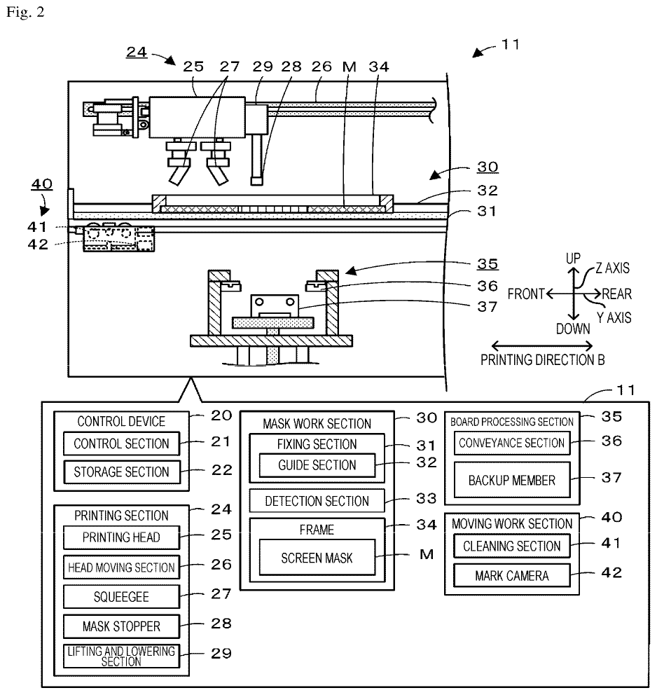

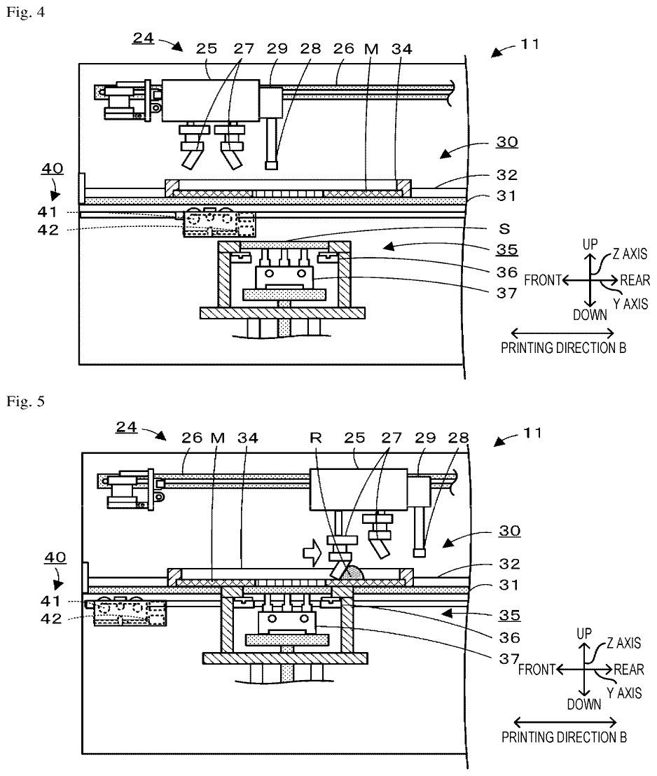

The present embodiment will be described below with reference to drawings. FIG. 1 is a schematic view illustrating an example of mounting system 10 and printing device 11 according to the present disclosure. FIG. 2 is a diagram illustrating an example of printing section 24, mask work section 30, and board processing section 35. Mounting system 10 includes printing device 11, print inspection device 12, storage device 13, mounting device 15, mounting inspection device 16, loader 18, a reflow device (not illustrated), and management computer (PC) 19. Mounting system 10 is configured as, for example, a production line in which mounting devices 15 for executing a mounting process of mounting component P on board S, which is a processing target, are aligned downstream of printing device 11 in a conveyance direction of board S. In the present embodiment, a left-right direction (an X axis), a front-rear direction (a Y axis), and an up-down direction (a Z axis) are as illustrated in FIG. 1, and FIGS. 4 to 8.

Print inspection device 12 is a device that inspects the state of a viscous fluid such as solder paste which is printed on board S by printing device 11. Storage device 13 is a temporary storage place for a feeder holding a component. Mounting device 15 is a device that executes a mounting process of placing component on board S. Mounting inspection device 16 is a device that inspects, for example, the state of the component mounted on board S. Loader 18 is a device that moves in the left-right direction along X-axis rails 17 on the front side of mounting device 15 to automatically attach and detach a mounting-related member such as a feeder used in mounting device 15, and collects and supplies the mounting-related member. The reflow device is a device that reflows a board on which solder is printed and component P is mounted. Management PC 19 is a device that manages information on each device of mounting system 10. Management PC 19 manages a progress status of each device in the production line which is involved in the mounting process.

As illustrated in FIG. 2, printing device 11 is a device that pushes solder as a viscous fluid that is placed on the upper surface of screen mask M into pattern holes formed in screen mask M using squeegees 27 to thereby print the solder onto board S, which is a processing target, below screen mask M, through the pattern holes. Here, examples of the “processing target” include, for example, board S on which a component is mounted, a base material that is a three-dimensional object, and the like. Examples of the “viscous fluid” include solder paste, conductive paste, an adhesive, and the like. Here, the following description will be made using board S and solder paste as examples. Screen mask M is fixed inside frame 34. As illustrated in FIG. 2, printing device 11 includes control device 20, printing section 24, mask work section 30, board processing section 35, and moving work section 40.

Control device 20 is configured as a microprocessor centered on control section 21 having CPU and controls entire printing device 11. Control device 20 includes control section 21 and storage section 22. Storage section 22 stores information and is a large-capacity storage medium such as an HDD or a flash memory. Storage section 22 stores a print job including information on board S to be subjected to a printing process and information on screen mask M, a printing process program for executing a printing process on board S, and the like. Control device 20 outputs a signal to printing section 24, mask work section 30, board processing section 35, and moving work section 40, as well as to management PC 19 as an external device. Control device 20 receives a signal from printing section 24, mask work section 30, board processing section 35, and moving work section 40, as well as from management PC 19 as an external device. As will be described in detail later, control section 21 executes a positioning process of acquiring position information indicating that screen mask M fixed to mask work section 30 and board S fixed to board processing section 35 are aligned with each other at a predetermined printing position. In addition, control section 21 causes storage section 22 to store the acquired position information, and executes a process of causing mask stopper 28 to be disposed, based on the stored position information, at a placement position where screen mask M stops at the aligned position.

Printing section 24 is disposed in an upper stage of printing device 11, and is a unit that executes a printing process of the viscous fluid onto board S using screen mask M. Printing section 24 includes, as illustrated in FIG. 2, printing head 25, head moving section 26, a squeegee lifting and lowering section (not illustrated), and squeegees 27. Printing head 25 is a unit in which squeegees 27 are vertically movably disposed. Head moving section 26 moves printing head 25 in predetermined printing direction B (here, the front-rear direction) to print, using squeegees 27, the viscous fluid that is placed on the upper surface of screen mask M, onto board S. Head moving section 26 includes a guide formed in the front-rear direction, a slider that moves along the guide, and a motor that drives the slider. Head moving section 26 includes a linear encoder (not illustrated), and can perform position control of printing head 25 with high precision. Squeegees 27 are disposed on a lower surface side of printing head 25 and are lifted or lowered by a squeegee lifting and lowering section. Printing section 24 has two squeegees 27 that are used respectively in the front-rear direction.

Printing head 25 is provided with mask stopper 28 and lifting and lowering section 29. Mask stopper 28 is a positioning member that is movable on mask work section 30, abuts against screen mask M, and stops screen mask M at a predetermined position. Mask stopper 28 is a columnar member and is disposed at the rear end portion of printing head 25 so as to be vertically movable. Mask stopper 28 is moved on mask work section 30 by head moving section 26. Head moving section 26 also functions as a stopper moving section that moves mask stopper 28. Lifting and lowering section 29 is a drive section that is disposed on printing head 25 and that lifts and lowers mask stopper 28 in an up-down direction. Lifting and lowering section 29 lifts and lowers mask stopper 28 among a positioning position where the tip end of mask stopper 28 abuts against screen mask M, a retracted position allowing screen mask M to pass, and a frame moving position where mask stopper 28 hooks onto the outer edge of frame 34.

Mask work section 30 is a unit that positions screen mask M to be insertable and removable, and places and fixes screen mask M in a horizontal orientation. Mask work section 30 is a unit that is disposed between printing section 24 and board processing section 35 in the up-down direction and fixes and holds screen mask M. Mask work section 30 includes fixing section 31 and detection section 33. Fixing section 31 supports screen mask M to be movable in the front-rear direction and fixes screen mask M at a predetermined printing position. Fixing section 31 has a central opening, and board S fixed to board processing section 35 is inserted into the opening. Fixing section 31 includes guide 32 that guides screen mask M along a predetermined insertion/removal direction, here, the front-rear direction. Guide 32 includes members that contact both sides of screen mask M, and one of the members is movable and fixable. When screen masks M of different sizes are guided, the width of the movable member changes. Detection section 33 is a sensor that detects a rough position of screen mask M. Detection section 33 may be, for example, a non-contact type sensor that is disposed along guide 32 and detects the position where an object is present by emitting and detecting light, or may be a contact type sensor that directly detects contact with the object. Control section 21 can detect whether screen mask M has reached the printing position based on the detection signal of detection section 33.

Board processing section 35 is a unit that is disposed below mask work section 30, conveys board S, which is a processing target, fixes conveyed board S, and brings board S into contact with and separates board S from screen mask M fixed to mask work section 30. Board processing section 35 includes conveyance section 36, backup member 37, and a lifting and lowering section (not illustrated). Conveyance section 36 conveys or fixes board S along a predetermined conveyance direction (left-right direction in FIG. 2). Backup member 37 is a member that supports board S from below. Backup member 37 includes a backup plate that is a flat plate-shaped member, a backup pin disposed on the backup plate, and the like. The lifting and lowering section lifts and lowers entire board processing section 35 and backup member 37.

Moving work section 40 is a unit that is disposed between mask work section 30 and board processing section 35, and moves in the front-rear direction of the device to work. The housing of moving work section 40 is moved in the front-rear direction along the Y axis by, for example, a Y-axis slider. Moving work section 40 includes cleaning section 41 and mark camera 42. Cleaning section 41 is a unit that abuts against a lower surface of screen mask M and wipes off substances adhering to the lower surface. Cleaning section 41 includes a roller that feeds the wiping paper, a roller that winds up the wiping paper, and an abutment portion that rises to abut against the lower surface of the screen mask M. Mark camera 42 is an imaging section that reads a reference mark formed on the lower surface of screen mask M and a reference mark formed on board S and acquires the positional relationship therebetween. Mark camera 42 is configured to simultaneously capture images of both the upper side and the lower side.

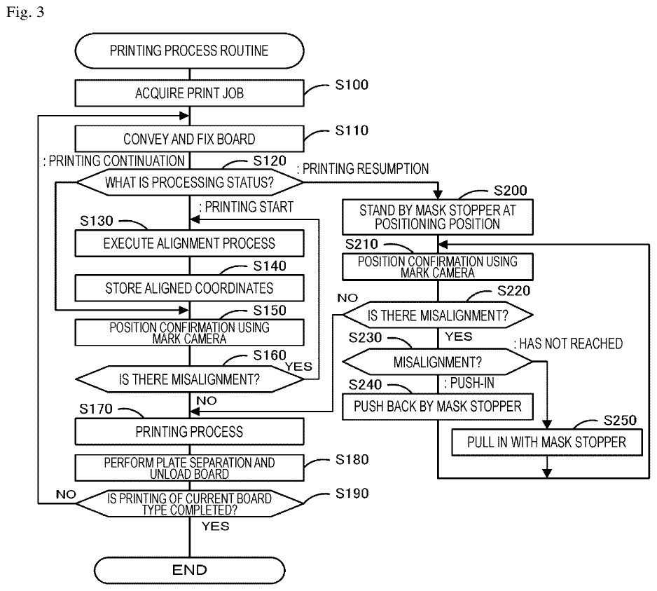

Next, a printing process of printing device 11 configured in the way described heretofore will briefly be described. FIG. 3 is a flowchart illustrating an example of a printing process routine executed by control section 21 of control device 20. This routine is executed by control section 21 in response to an input from worker W after printing device 11 is activated. Before executing the printing process, worker W fixes screen mask M used for the current printing process to frame 34, aligns the width of guide 32 with frame 34, and inserts frame 34 into mask work section 30. At this time, worker W also performs the work of placing solder paste onto screen mask M.

When the printing process routine is started, control section 21 first acquires, by reading from storage section 22, a print job including information on board S to be manufactured this time (S100). Next, control section 21 causes board processing section 35 to convey board S and fix board S at the printing position (S110). When board S is fixed, control section 21 determines the current processing status (S120). When the current processing status is printing start, control section 21 executes a process of aligning board S with and bringing board S into contact with screen mask M by board processing section 35 (S130), and executes a positioning process of storing the aligned coordinates in storage section 22 as position information (S140). Further, control section 21 captures images of screen mask M and board S using mark camera 42 and confirms the positional relationship therebetween (S150). FIG. 4 is a diagram illustrating an example of position confirmation using mark camera 42 in the printing process. As illustrated in FIG. 4, mark camera 42 captures an image of the area between mask work section 30 and board processing section 35, whereby control section 21 can acquire the positional relationship between screen mask M and board S. When, at S150, there is misalignment between screen mask M and board S, control section 21 executes the processing from S130 onward. That is, control section 21 repeatedly executes the alignment process until no misalignment is confirmed using mark camera 42. When the alignment is completed, control section 21 causes storage section 22 to finally store the coordinates. For example, control section 21 causes storage section 22 to store the coordinates of the rear end position that is on the right end side of frame 34 in FIG. 2.

When the positioning process is completed and it is determined in S160 that there is no misalignment, control section 21 causes printing head 25 to execute a printing process of applying solder onto board S (S170). FIG. 5 is a diagram illustrating an example of a printing operation by squeegees 27 in the printing process. As illustrated in FIG. 5, control section 21 brings board S into close contact with screen mask M at the aligned position, scans squeegees 27 in printing direction B, and prints solder R on screen mask M onto board S. Subsequently, control section 21 causes board processing section 35 to perform plate separation to separate board S from screen mask M, and to unload board S (S180). Then, control section 21 determines whether all of boards S currently being printed have completed the printing process (S190), and when not all of current boards S have completed, control section 21 executes the processing from S110 onward. On the other hand, when the printing process of all current boards S has been completed, control section 21 ends this routine.

On the other hand, when, at S120, the current processing status is printing continuation, control section 21 confirms, in S150, the positional relationship between board S and screen mask M conveyed in at S110 using mark camera 42, and when there is misalignment, control section 21 executes the processing from S130 onward. That is, control section 21 executes the positioning process of screen mask M to eliminate the misalignment. On the other hand, when there is no misalignment in S160, control section 21 executes the printing process in S170, and executes the processing from S180 onward.

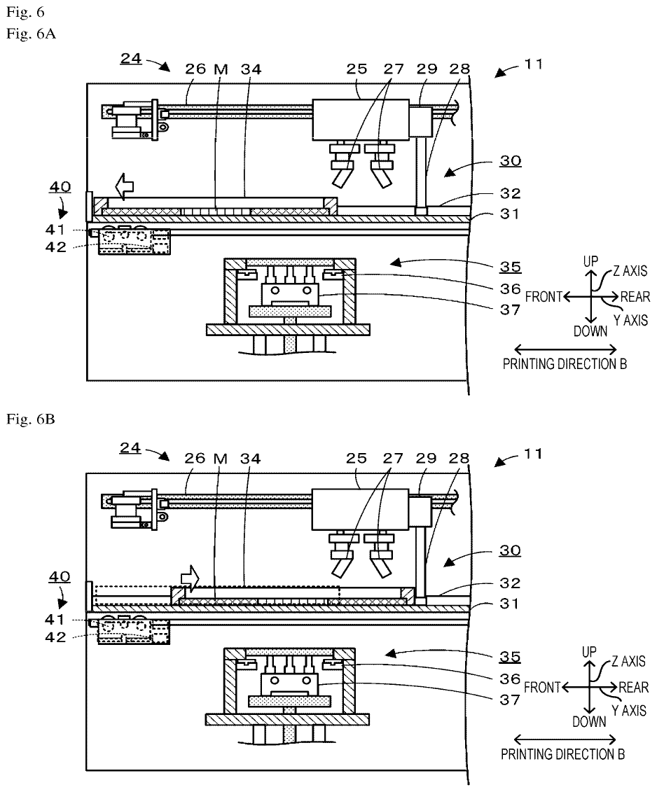

On the other hand, when, at S120, the current processing status is printing resumption, control section 21 causes mask stopper 28, based on the coordinates stored in S140, to stand by at the placement position where screen mask M is disposed at the same position as in the positioning process (S200). In printing device 11, the printing process may be interrupted and screen mask M pulled out, for example, when worker W supplies solder paste onto screen mask M or cleans screen mask M. The printing resumption may include, for example, a case where the printing process is resumed after being interrupted due to such work performed by worker W. FIG. 6 is a diagram illustrating an example of standby at the placement position of mask stopper 28, in which FIG. 6A illustrates a state where screen mask M is pulled out, and FIG. 6B illustrates a state where screen mask M is pushed in until screen mask M abuts against mask stopper 28. In printing device 11, when screen mask M is pulled out by worker W, mask stopper 28 is caused to stand by at the placement position of screen mask M so that screen mask M is returned to the original position (FIG. 6A). Control section 21 may cause mask stopper 28 to be disposed at the placement position when same screen mask M is inserted or removed. Worker W, after pulling out screen mask M, pushes in frame 34 toward the back of mask work section 30 until frame 34 is pressed against mask stopper 28 after completing the work (FIG. 6B), and then inputs a command to resume the printing process via an operation panel (not illustrated).

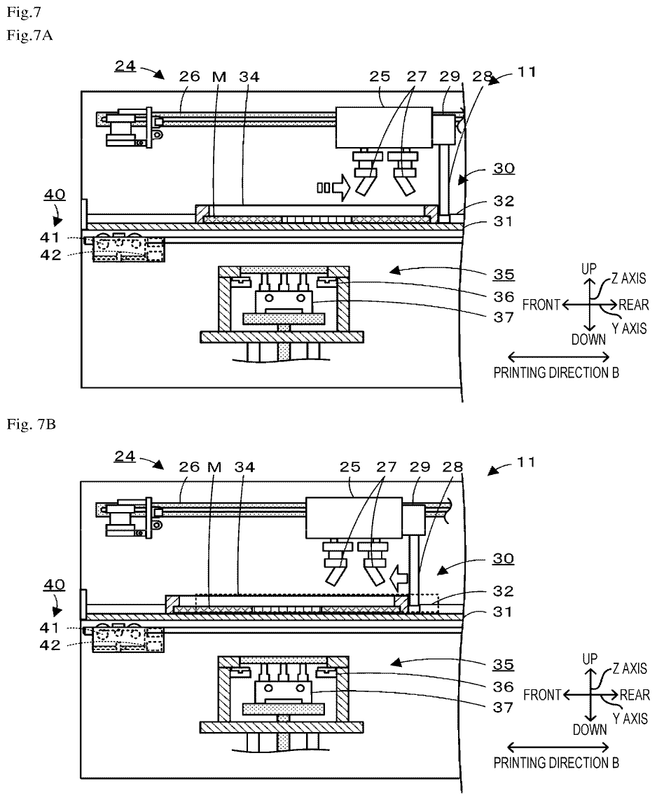

Next, control section 21 captures images of screen mask M and board S using mark camera 42, confirms the positional relationship therebetween (S210, see FIG. 4), and determines whether there is misalignment (S220). When there is no misalignment in screen mask M, control section 21 omits the positioning process of screen mask M and executes the processing from S170 onward, that is, the printing process. At this time, when the content of the printing process remains unchanged, even when the fixation of screen mask M is released at mask work section 30, control section 21 may omit re-execution of the positioning process. On the other hand, when screen mask M is misaligned from the aligned position, control section 21 confirms the state of the misalignment (S230), and executes a position adjustment process in which mask stopper 28 adjusts the position of screen mask M to the aligned position (S240 to S250). Control section 21 can determine the state of the misalignment based on the detection value of detection section 33. For example, when screen mask M is pushed in and mask stopper 28 is misaligned with the placement position, the position adjustment process of pushing back the mask stopper 28 is executed based on the position information stored in storage section 22 (S240). FIG. 7 is a diagram illustrating an example of the position adjustment process when screen mask M is excessively pushed in, in which FIG. 7A illustrates a state where screen mask M is excessively pushed in, and FIG. 7B illustrates a state where frame 34 is pushed back by mask stopper 28. As illustrated in FIG. 7A, when frame 34 is pushed in to such an extent that mask stopper 28 is misaligned from the placement position, control section 21 executes a process of pushing frame 34 back to the placement position by mask stopper 28 (FIG. 7B). As a result of the position adjustment process, the position of screen mask M becomes appropriate, so that worker W is not required to perform the work again, and control section 21 can execute the printing process as is without executing the positioning process.

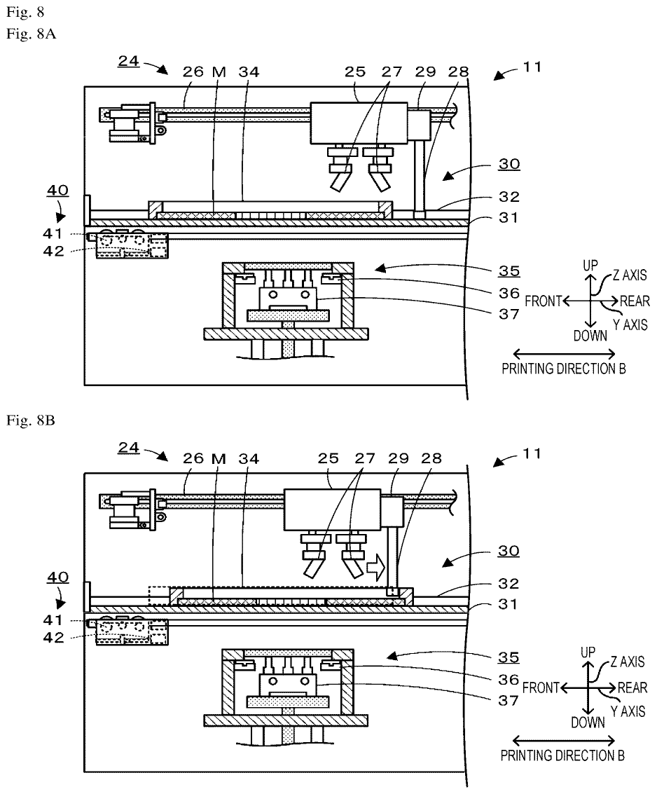

On the other hand, when, at S230, screen mask M is not sufficiently pushed in and has not reached mask stopper 28, control section 21 executes the work of pulling frame 34 toward the placement position side by mask stopper 28 (S250). Here, control section 21 causes head moving section 26, based on the position information stored in the positioning process, to move mask stopper 28 so that mask stopper 28 hooks onto a portion of screen mask M and pulls in screen mask M. FIG. 8 is a diagram illustrating an example of the position adjustment process when screen mask M has not reached mask stopper 28, in which FIG. 8A illustrates a state where frame 34 has not reached mask stopper 28, and FIG. 8B illustrates a state where frame 34 is pulled in by mask stopper 28. Control section 21 can grasp an approximate position of frame 34 based on the detection value of detection section 33 (FIG. 8A). Control section 21 lowers mask stopper 28 so that the tip end of mask stopper 28 hooks onto the inner edge of frame 34, and moves printing head 25 to the rear portion side to pull in frame 34 (FIG. 8B). After frame 34 is pulled in beyond the aligned position, control section 21 may cause mask stopper 28 to push frame 34 back to the placement position, as illustrated in FIG. 7B. As a result of the position adjustment process, the position of screen mask M becomes appropriate, so that worker W is not required to perform the work again, and control section 21 can execute the printing process as is without executing the positioning process. After S240 or S250, control section 21 determines in S220 whether there is misalignment, and when there is no misalignment, control section 21 executes the processing from S170 onward.

Here, a correspondence relationship between the elements of the present embodiment and the elements of the present disclosure will be clarified. Mask work section 30 of the present embodiment corresponds to an example of a mask work section of the present disclosure, board processing section 35 corresponds to an example of a target processing section, mask stopper 28 corresponds to an example of a mask stopper, storage section 22 corresponds to an example of a storage section, and control section 21 corresponds to an example of control section. In addition, printing device 11 corresponds to a printing device, printing head 25 corresponds to a printing head, squeegee 27 corresponds to a squeegee, head moving section 26 corresponds to a stopper moving section, screen mask M corresponds to a screen mask, solder R corresponds to a viscous fluid, and board S corresponds to a processing target. In the present embodiment, an example of a printing method of the present disclosure is also clarified by describing operations of printing device 11.

Printing device 11 of the present embodiment described above is a device that prints, using squeegees 27, solder R as the viscous fluid that is placed on the upper surface of screen mask M, onto board S, which is a processing target. Printing device 11 includes: mask work section 30 configured to place and fix screen mask M so that screen mask M is insertable and removable; board processing section 35 as a target processing section configured to convey and fix board S, which is a processing target; mask stopper 28 configured to move on mask work section 30, to abut against screen mask M, and to stop screen mask M at a predetermined position; storage section 22 configured to store information; and control section 21 configured to execute a positioning process of acquiring position information indicating that screen mask M fixed to mask work section 30 and board S fixed to board processing section 35 are aligned with each other at a predetermined printing position, to cause storage section 22 to store the acquired position information, and to cause mask stopper 28 to be disposed, based on the stored position information, at a placement position where screen mask M stops at the aligned position. In printing device 11, once the positional information indicating that screen mask M and board S are aligned with each other is acquired, since mask stopper 28 is disposed at the placement position based on the positional information, the re-execution of the positioning process of screen mask M can be omitted, so that the printing process can be executed more efficiently.

In addition, printing device 11 includes head moving section 26 as a stopper moving section that moves mask stopper 28 on mask work section 30, and, when screen mask M is misaligned from the aligned position, control section 21 executes a position adjustment process of causing head moving section 26 to move mask stopper 28 so that mask stopper 28 adjusts the position of screen mask M to the aligned position. In printing device 11, for example, even when screen mask M is inserted or removed at a misaligned position, screen mask M is automatically adjusted to an appropriate position by mask stopper 28, so that the printing process can be executed more efficiently without requiring the work of worker W. When screen mask M is pushed in and mask stopper 28 is misaligned with the placement position, control section 21 causes head moving section 26, based on the stored position information, to push mask stopper 28 back to the placement position. In printing device 11, when screen mask M is pushed back by mask stopper 28, screen mask M is automatically adjusted to an appropriate position, so that the printing process can be executed more efficiently without requiring the work of worker W. Further, when screen mask M is not sufficiently pushed in and screen mask M has not reached mask stopper 28, control section 21 causes head moving section 26, based on the stored position information, to move mask stopper 28 so that mask stopper 28 hooks onto a portion of screen mask M and pulls in screen mask M. In printing device 11, when screen mask M is pulled in by mask stopper 28, screen mask M is automatically adjusted to an appropriate position, so that the printing process can be executed more efficiently without requiring the work of worker W.

In addition, in printing device 11, control section 21 causes mask stopper 28 to be disposed at the placement position when same screen mask M is inserted or removed. In printing device 11, when screen mask M is inserted or removed with fixation of screen mask M released, the screen mask M is disposed at an appropriate position by the mask stopper 28 being disposed, and thus the printing process can be executed more efficiently. Further, when the content of the printing process remains unchanged, even when the fixation of screen mask M is released at mask work section 30, control section 21 may omit the re-execution of the positioning process. In this printing device, since the screen mask M is disposed at the aligned position by the mask stopper 28, the re-execution of the positioning process can be omitted, so that the printing process can be executed more efficiently. Furthermore, mask work section 30 includes guide 32 that guides the screen mask M along a predetermined insertion/removal direction. In printing device 11, since the movement direction of the mask stopper 28 needs only to be along the insertion/removal direction, the device configuration can be further simplified. Furthermore, mask stopper 28 is disposed on printing head 25 that is movable in predetermined printing direction B and on which squeegees 27 are disposed. In printing device 11, a mechanism that moves mask stopper 28 can be omitted, and the device configuration can be further simplified.

Here, the printing device and the printing method of the present disclosure are not limited to those described in the embodiment at all, and hence, it goes without saying that the printing device and the printing method can be carried out in various aspects without departing from the technical scope of the present disclosure.

For example, in the embodiment described above, when screen mask M is misaligned from the aligned position, control section 21 causes mask stopper 28 to adjust the position of screen mask M to the aligned position, but the present disclosure is not particularly limited thereto, and the position adjustment process may be omitted. For example, when screen mask M is pushed in and mask stopper 28 is misaligned with the placement position, control section 21 causes mask stopper 28 to be pushed back to the placement position, but this process may be omitted. Alternatively, when screen mask M is not sufficiently pushed in and screen mask M has not reached mask stopper 28, control section 21 causes mask stopper 28 to hook onto a portion of screen mask M and pull in screen mask M, but this process may be omitted. In printing device 11 as well, since mask stopper 28 is disposed at the placement position, the printing process can be executed more efficiently.

In the embodiment described above, control section 21 may cause mask stopper 28 to be disposed at the placement position when same screen mask M is inserted or removed, but the present disclosure is not particularly limited thereto. In addition, when the content of the printing process remains unchanged, even when the fixation of screen mask M is released at mask work section 30, control section 21 omits the re-execution of the positioning process, but the present disclosure is not particularly limited thereto.

In the embodiment described above, mask stopper 28 is disposed on printing head 25 that is movable in printing direction B and is moved by head moving section 26, but the present disclosure is not particularly limited thereto, and mask stopper 28 may be disposed on a member other than printing head 25 or may be moved by a stopper moving section other than head moving section 26. In printing device 11, it is more preferable from the viewpoint of simplifying the device configuration that mask stopper 28 is disposed on printing head 25 capable of performing the position control with high precision.

In the embodiment described above, printing device 11 including mask stopper 28 has been described, but the present disclosure is not particularly limited thereto. The present disclosure may be embodied as any of the following: a configuration consisting solely of control device 20 configured to control mask stopper 28; a control method for printing device 11; or a printing method. In control device 20, the control method for the printing device, and the printing method as well, the printing process can be executed more efficiently by causing mask stopper 28 to stand by at the placement position.

Here, the printing method of the present disclosure may be configured as follows. For example, the printing method of the present disclosure is a printing method executed by a printing device including a mask work section, a target processing section, a mask stopper, and a storage section, the printing method including:
(a) a step of executing a positioning process of acquiring position information indicating that a screen mask fixed to the mask work section and a processing target fixed to the target processing section are aligned with each other at a predetermined printing position;
(b) a step of causing the storage section to store the position information acquired in the step (a); and
(c) a step of causing, based on the position information stored in the step (b), the mask stopper to be disposed at a placement position where the screen mask stops at the aligned position,
in which the mask work section is configured to place and fix the screen mask so that the screen mask is insertable and removable, the target processing section is configured to convey and fix the processing target, the mask stopper is configured to move on the mask work section, to abut against the screen mask, and to stop the screen mask at a predetermined position, the storage section is configured to store information, and the printing device is configured to print, using a squeegee, a viscous fluid that is placed on an upper surface of the screen mask, onto the processing target.

In this printing method, as in the printing device described above, since the mask stopper is disposed at the placement position based on the position information indicating that the screen mask and the processing target are aligned with each other, the re-execution of the positioning process can be omitted, so that the printing process can be executed more efficiently. This printing method may adopt any of the aspects of the printing device described above, or may include a step of expressing the function of any of the printing devices described above.

### INDUSTRIAL APPLICABILITY

The present disclosure is applicable to a technical field of devices for executing a mounting process of a component.

### REFERENCE SIGNS LIST

10: mounting system, 11: printing device, 12: print inspection device, 13: storage device, 14: automated guided vehicle, 15: mounting device, 16: mounting inspection device, 17: X-axis rail, 18: loader, 19: management PC, 20: control device, 21: control section, 22: storage section, 24: printing section, 25: printing head, 26: head moving section, 27: squeegee, 28: mask stopper, 29: lifting and lowering section, 30: mask work section, 31: fixing section, 32: guide, 33: detection section, 34: frame, 35: board processing section, 36: conveyance section, 37: backup member, B: printing direction, M: screen mask, R: solder, S: board, W: worker.

1. A printing device for printing, using a squeegee, a viscous fluid that is placed on an upper surface of a screen mask, onto a processing target, the printing device comprising:
a mask work section configured to place and fix a screen mask so that the screen mask is insertable and removable;
a target processing section configured to convey and fix a processing target;
a mask stopper configured to move on the mask work section, to abut against the screen mask, and to stop the screen mask at a predetermined position,
a storage section configured to store information; and
a control section configured to execute a positioning process of acquiring position information indicating that the screen mask fixed to the mask work section and the processing target fixed to the target processing section are aligned with each other at a predetermined printing position, to cause the storage section to store the acquired position information, and to cause the mask stopper to be disposed, based on the stored position information, at a placement position where the screen mask stops at the aligned position.

2. The printing device according to claim 1, further comprising:
a stopper moving section configured to move the mask stopper on the mask work section,
wherein, when the screen mask is misaligned from the aligned position, the control section causes the stopper moving section to move the mask stopper so that the mask stopper adjusts the position of the screen mask to the aligned position.

3. The printing device according to claim 2, wherein, when the screen mask is pushed in and the mask stopper is misaligned with the placement position, the control section causes the stopper moving section, based on the stored position information, to push the mask stopper back to the placement position.

4. The printing device according to claim 2, wherein, when the screen mask is not sufficiently pushed in and the screen mask has not reached the mask stopper, the control section causes the stopper moving section, based on the stored position information, to move the mask stopper so that the mask stopper hooks onto a portion of the screen mask and pulls in the screen mask.

5. The printing device according to claim 1, wherein, when the same screen mask is inserted or removed, the control section causes the mask stopper to be disposed at the placement position.

6. The printing device according to claim 1, wherein, when a content of the printing process remains unchanged, even when the fixation of the screen mask is released at the mask work section, the control section omits re-execution of the positioning process.

7. The printing device according to claim 1, wherein the mask work section includes a guide section configured to guide the screen mask along a predetermined insertion/removal direction.

8. The printing device according to claim 1, wherein the mask stopper is disposed on a printing head that is movable in a predetermined printing direction and on which the squeegee is disposed.

9. A printing method executed by a printing device including a mask work section, a target processing section, a mask stopper, and a storage section, the printing method comprising:
(a) a step of executing a positioning process of acquiring position information indicating that a screen mask fixed to the mask work section and a processing target fixed to the target processing section are aligned with each other at a predetermined printing position;
(b) a step of causing the storage section to store the position information acquired in the step (a); and (c) a step of causing, based on the position information stored in the step (b), the mask stopper to be disposed at a placement position where the screen mask stops at the aligned position,
wherein the mask work section is configured to place and fix the screen mask so that the screen mask is insertable and removable, the target processing section is configured to convey and fix the processing target, the mask stopper is configured to move on the mask work section, to abut against the screen mask, and to stop the screen mask at a predetermined position, the storage section is configured to store information, and the printing device is configured to print, using a squeegee, a viscous fluid that is placed on an upper surface of the screen mask, onto the processing target.
